(19) United States
(12) Patent Application Publication
(10) Pub. No.: US 2015/0069602 A1
(43) Pub. Date: Mar. 12, 2015

(54) CHIP-ON-FILM DEVICE

(71) Applicant: Novatek Microelectronics Corp., Hsinchu (TW)

(72) Inventors: Chiao-Ling Huang, New Taipei City (TW); Tai-Hung Lin, Hsinchu City (TW)

(21) Appl. No.: 14/549,551

(22) Filed: Nov. 21, 2014

Related U.S. Application Data
(62) Division of application No. 13/659,932, filed on Oct. 25, 2012.
(60) Provisional application No. 61/643,356, filed on May 7, 2012.

(30) Foreign Application Priority Data
Aug. 16, 2012 (TW) 101129796

(51) Int. Cl. H01L 23/00

(52) U.S. Cl. CPC H01L 24/13; H01L 2224/13026; H01L 2224/13016; H01L 2224/0401; H01L 2224/05144; H01L 2224/05124; H01L 2224/29166; H01L 2224/29184; H01L 2924/2064; H01L 2224/29082
USPC 257/737

(57) ABSTRACT

A chip-on-film device including a flexible circuit film having a wire, a passivation layer having a hole, an adhesive layer, a first pad, a second pad, an interconnection, and a bump is provided. A part of the adhesive layer is disposed in the hole. The first pad and the second pad are disposed under the passivation layer.

A part of the interconnection is disposed under the passivation layer, and disposed between the first pad and the second pad. The bump is electrically connected to the first pad via the adhesive layer. The bump is welded on the wire. A part of a first part of the bump overlaps the first pad, a second part of the bump extends to an outside of the pad and at least partially overlaps the interconnection, and the third part of the bump overlaps the second pad.

### CROSS-REFERENCE TO RELATED APPLICATION

This application is a Divisional of and claims the priority benefit of U.S. patent application Ser. No. 13/659,932, filed on Oct. 25, 2012. The prior U.S. application Ser. No. 13/659,932 claims the priority benefits of U.S. provisional application Ser. No. 61/643,356, filed on May 7, 2012 and Taiwan application serial no. 101129796, filed on Aug. 16, 2012. The entirety of each of the above-mentioned patent applications is hereby incorporated by reference herein and made a part of this specification.

### BACKGROUND OF THE INVENTION

1. Field of the Invention

The invention is related to an integrated circuit (IC), and more specifically, to a chip-on-film (COF) device.

2. Description of Related Art

The COF device is to weld/package the IC onto a flexible circuit film. A metal bump is disposed on a corresponding Al pad in the IC. The metal bump is welded to the Al pad to facilitate the metal bump to be electrically connected to a core circuit. A back-end package process of the COF is by heating with high temperature in order to generate a eutectic reaction between the metal bump on the IC and a tinned metal on the flexible circuit film.

In order to coordinate with the back-end package process, the metal bump on the IC has to be big enough to be able to be welded on the tinned metal of the flexible circuit film easily. In a conventional IC layout of the COF device, an area of the Al pad is bigger than the metal bump, and the metal bump completely overlaps on the Al pad along a perpendicular direction of the IC. The Al pad of this conventional COF device occupies a large area of the IC and even affects a routing design of the metal interconnection (such as a supply wire, a ground wire or a data wire).

### SUMMARY OF THE INVENTION

The invention provides a chip-on-film (COF) device that is capable of effectively reducing a pad area.

According to an aspect, a COF device is provided, including a flexible circuit film, a passivation layer, a first adhesive layer, a first pad, a second pad, a first metal interconnection, and a metal bump. The flexible circuit film includes at least a wire. The passivation layer includes at least a first hole. At least a part of the first adhesive layer is disposed in the first hole. The first pad is disposed under the passivation layer, and at least a part of the first pad is disposed under the first hole. The second pad is disposed under the passivation layer and on a first side of the first pad. At least a part of the first metal interconnection is disposed under the passivation layer, and disposed at the first side of the first pad, and disposed between the first pad and the second pad, wherein the first metal interconnection does not touch the first pad and the second pad. At least a part of the metal bump is disposed on the first adhesive layer, and the metal bump is electrically connected to the first pad via the first adhesive layer and welded on the at least one wire. The metal bump includes a first part, a second part and a third part. At least a part of the first part overlaps the first pad along a perpendicular direction of the COF device. The second part extends to an outside of the first pad along a first horizontal direction of the COF device and partially overlaps the first metal interconnection. At least part of the third part overlaps the second pad along the perpendicular direction of the COF device.

As described above, in the embodiments of the invention, the first part of the metal bump overlaps the first pad along the perpendicular direction of the COF device, and the second part of the metal bump overlaps the metal interconnection (such as a supply wire, a ground wire, a data wire, or other wires) outside the pad, and the third part of the metal bump overlaps the second pad along the perpendicular direction of the COF device. Therefore, the COF device is capable of effectively reducing the area of the pad to facilitate the routing design of the metal interconnection.

In order to make the aforementioned features and advantages of the invention more comprehensible, embodiments accompanying figures are described in details below.

### BRIEF DESCRIPTION OF THE DRAWINGS

The accompanying drawings are included to provide further understanding and are incorporated in and constitute a part of this specification. The drawings illustrate exemplary embodiments and, together with the description, serve to explain the principles of the invention.

FIG. 1 is a schematic top view of a COF device according to an embodiment of the invention.

FIG. 2 is a schematic cross-sectional view along the line A-A′ in FIG. 1, illustrating a COF device according to an embodiment of the invention.

FIG. 3 is a schematic cross-sectional view along the line A-A′ in FIG. 1, illustrating a COF device according to another embodiment of the invention.

FIGS. 4-7 are schematic views illustrating a layout of the disposition of the pad, the metal interconnections, and the metal bump illustrated in FIG. 1 on an integrated circuit according to another embodiment of the invention.

FIG. 8 is a schematic top view of a COF device according to another embodiment of the invention.

FIG. 9 is a schematic cross-sectional view along the line B-B′ in FIG. 8, illustrating a COF device according to an embodiment of the invention.

FIG. 10 is a schematic top view of a COF device according to yet another embodiment of the invention.

FIG. 11 is a schematic cross-sectional view along the line C-C′ in FIG. 10, illustrating a COF device according to an embodiment of the invention.

### DESCRIPTION OF EMBODIMENTS

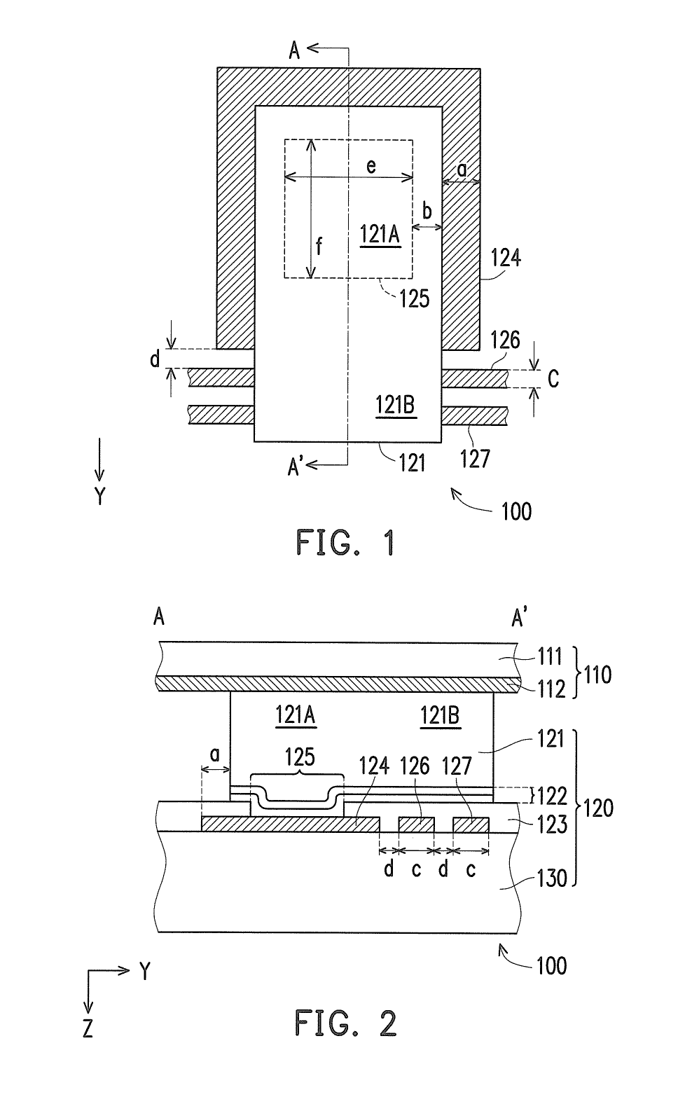

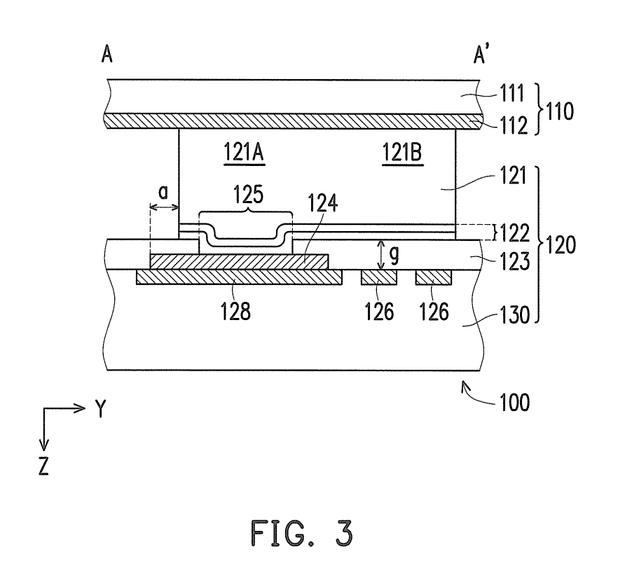

FIG. 1 is a schematic top view of a chip-on-film (COF) device 100 according to an embodiment of the invention. FIG. 2 is a schematic cross-sectional view along the line A-A′ in FIG. 1, illustrating the COF device 100 according to an embodiment of the invention. Referring to FIGS. 1 and 2, the COF device 100 includes a flexible circuit film 110 and an integrated circuit 120. The flexible circuit film 110 includes a film 111 and at least a wire 112. The wire 112 with a conductive material is disposed on a surface of the film 111.

A substrate 130 of the integrated circuit 120 illustrated in FIG. 2 is only schematically presented. In fact, there may be various kinds of electrical elements, doped regions, metal layers, insulating layers, polysilicon layers, contact plugs, via plugs and/or other integrated circuit components inside, above, or under the substrate 130. The integrated circuit 120 further includes a metal bump 121, an adhesive layer 122, a passivation layer 123, a pad 124, and at least a metal interconnection (such as 126 and 127 illustrated in FIGS. 1 and 2).

The passivation layer 123 is disposed on the substrate 130 of the integrated circuit 120. The passivation layer 123 includes a hole 125. The pad 124 is disposed under the passivation layer 123 and on the substrate 130. As illustrated in FIGS. 1 and 2, at least a part of the pad 124 is disposed under the hole 125. The pad 124 may be an aluminum pad, a gold pad, or other conductive materials. At least a part of each of the metal interconnections 126 and 127 is disposed under the passivation layer 123 and on a side of the pad 124. Neither of the metal interconnections 126 and 127 touches the pad 124. The metal interconnections 126 and 127 are the supply wire, ground wire, data wire, control wire, floating metal, or other wires of the integrated circuit 120 respectively.

The adhesive layer 122 is disposed on the passivation layer 123. A part of the adhesive layer 122 is disposed in the hole 125. At least a part of the metal bump 121 is disposed on the adhesive layer 122, and the metal bump 121 is electrically connected to the pad 124 via the adhesive layer 122. The metal bump 121 may be a gold bump or other metallic material. The adhesive layer 122 may be a titanium tungsten layer, which is the adhesive layer 122 formed by a titanium layer and a tungsten layer, or the adhesive layer 122 formed by a titanium-tungsten alloy. In other embodiments, a material for the adhesive layer 122 may be other conductive materials used as a welding medium between the metal bump 121 and the pad 124. In some embodiments, based on the collocation of the materials of the metal bump 121 and the pad 124, both of the metal bump 121 and the pad 124 have an excellent adhesion; therefore, the adhesive layer 122 may be omitted, and the metal bump 121 and the pad 124 may be bonded directly.

An area ratio of the hole 125 and the metal bump 121 may be 40% to 50% on a perpendicular direction Z of the COF device 100. In the present embodiment, the area ratio of the hole 124 and the metal bump may be set at 20% to 40%.

For example, on the perpendicular direction Z of the COF device 100, a shorter side of the hole 125 (such as the side marked with e in FIG. 1) is greater than 12 μm, and a longer side (such as the side marked with f in FIG. 1) is greater than 35 μm.

A distance b from an edge of the hole 125 to an edge of the metal bump 121 is greater than 3 μm. If the value of b is too small, an eutectic alloy might be formed by the Al in the pad 124 and the Au in the metal bump and cause a defect. A distance a from an edge of a first part 121A of the metal bump 121 to an edge of the pad 124 is greater than 3 μm. If the value of a is too small, an alignment error might occur in a manufacturing process. Therefore, when a size of the metal bump 121 is designed, a size of the pad 124 and a size of the hole 125 need to be put into consideration at the same time.

The metal bump 121 includes the first part 121A and a second part 121B. At least a part of the first part 121A along the perpendicular direction Z of the COF device 100 overlaps the pad 124. The second part 121B extends to an outside of the pad 124 along a horizontal direction Y of the COF device 100, and at least part of the second part 121B overlaps the metal interconnections 126 and 127. This may be a Bump on Active (BOA) design. The passivation layer 123 is disposed between the metal bump 121 and the metal interconnections 126 and 127. For example, a width c of each of the metal interconnections 126 and 127 is 0.1 μm to 40 μm. A distance d from an edge of the metal interconnection 126 to an edge of the pad 124 is greater than 0.1 μm, and a height difference caused by the metal interconnections can be prevented from being too far apart.

In a back-end package process of the COF device 100, a high temperature, for example, is applied to heat up the metal bump 121 on the integrated circuit 120 and the wire 112 on the flexible circuit film 110 to generate a eutectic reaction in order for the metal bump 121 to be welded to the wire 112. In the present embodiment, a hardness of the metal bump 121 is 25-100 Hv, 40-70 Hv, or 40-50 Hv. When the COF device 100 is compressed with the integrated circuit 120, if the hardness of the material used for the metal bump 121 is too high (higher than 70 Hv, for example), a crazing issue may occur on the wire 112 and/or the metal bump 121 and affect a reliability. If the hardness of the material used for the metal bump 121 is too low (lower than 40 Hv, for example), then skew of a lead angle due to a bad compression may easily be caused when the COF device 100 is compressed with the integrated circuit 120.

A surface roughness of the metal bump 121 is 0.05-2 μm or 0.8-1.2 μm. The surface roughness may be controlled through a manufacturing process of disposing the metal bump. When the COF device 100 is compressed with the integrated circuit 120, the surface roughness being too high (higher than 2 μm, for example) may cause a poor contact between the metal bump 121 and the wire 112. The surface roughness being too small (smaller than 0.05 μm, for example) may cause the metal bump 121 to slip to an outer region of the wire 112.

As described above, since the first part 121A of the metal bump 121 overlaps the pad 124 along the perpendicular direction Z of the COF device 100, and the second part 121B of the metal bump 121 overlaps the metal interconnections (such as 126 and/or 127) outside the pad 124, the COF device 100 is capable of effectively reducing the area of the pad 124 to facilitate the a routing design of the metal interconnections.

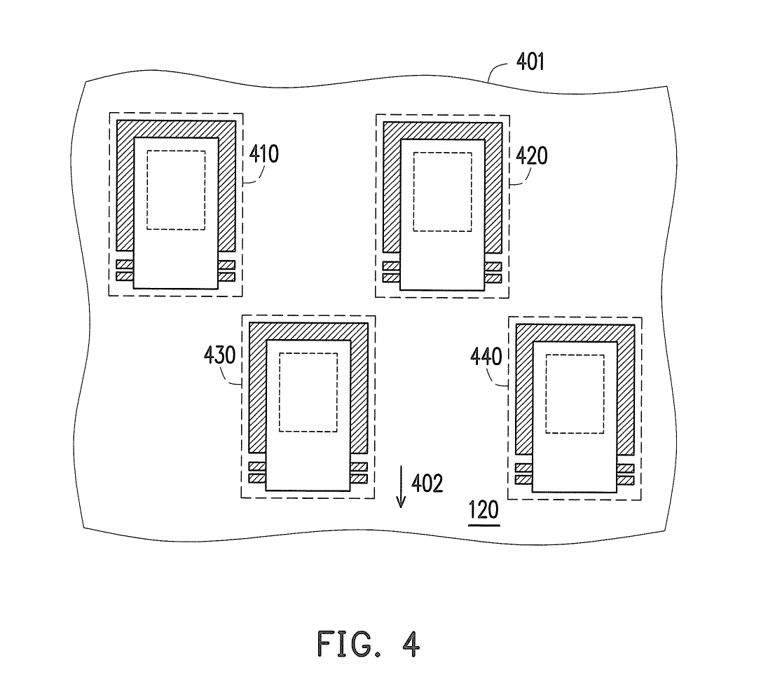

FIG. 3 is a schematic cross-sectional view along the line A-A′ in FIG. 1, illustrating a COF device 100 according to another embodiment of the invention. For the embodiment illustrated in FIG. 3, a relevant description of FIG. 2 may be referred to. The embodiment of FIG. 3 further includes at least a metal layer 128, which is different from the embodiment of FIG. 2. The metal layer 128 is disposed under the pad 124, and the metal layer 128 is electrically connected to the pad 124. As illustrated in the embodiment of FIG. 3, the metal interconnections 126 and 127 are disposed next to the metal layer 128. The metal interconnection 126, the metal interconnection 127, and the metal layer 128 belong to a same layer. A distance (such as the distance marked with g in FIG. 3) between the metal interconnections and the metal bump needs to be smaller than 100 um in order to prevent an issue of the metal bump 121 being tilted due to an uneven stress during the compression of the IC. The metal interconnection 126, the metal interconnection 127, and the metal layer 128 may belong to different layers in other embodiments.

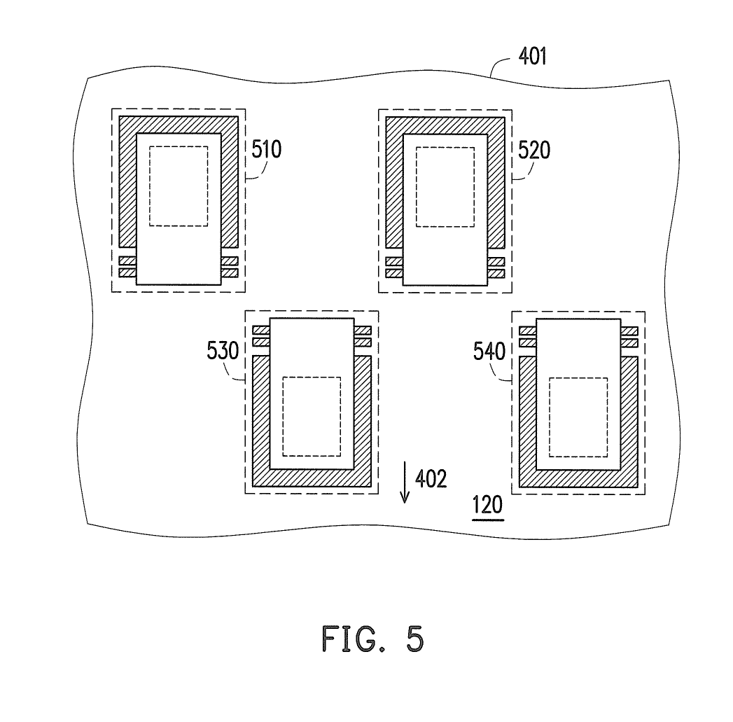

FIG. 4 is a schematic view illustrating a layout of the disposition of the pad, the metal interconnections, and the metal bump illustrated in FIG. 1 on the integrated circuit 120 according to an embodiment of the invention. For pad structures 410, 420, 430, and 440 of the integrated circuit 120 illustrated in FIG. 4, a relevant description of

FIG. 1 may be referred to. As illustrated in the embodiment of FIG. 1, the pad structures 410-440 each includes a BOA (Bump on Active) structure (i.e. the bump is on top of an active region). The pad structures 410-440 are divided into two rows. One of the rows near an edge 401 of the integrated circuit 120 includes the pad structures 410 and 420. The other row near a center 402 of the integrated circuit 120 includes the pad structures 430 and 440. In the embodiment as illustrated in FIG. 4, part of all of the BOA structures of the pad structures 410-440 faces a direction of the center 402 of the integrated circuit 120.

FIG. 5 is a schematic view illustrating a layout of the disposition of the pad, the metal interconnections, and the metal bump illustrated in FIG. 1 on the integrated circuit 120 according to another embodiment of the invention. For pad structures 510, 520, 530, and 540 of the integrated circuit 120 illustrated in FIG. 5, a relevant description of FIG. 1 may be referred to. As illustrated in the embodiment of FIG. 1, the pad structures 510-540 each has a BOA structure. The pad structures 510-540 are divided into two rows. One of the rows near the edge 401 of the integrated circuit 120 includes the pad structures 510 and 520. The other row near the center 402 of the integrated circuit 120 includes the pad structures 530 and 540. In the embodiment as illustrated in FIG. 5, all of the BOA structures of the pad structures 510 and 520 on an outer row face a direction of the center 402 of the integrated circuit 120. All of the BOA structures of the pad structures 530 and 540 on an inner row face a direction of the edge 401 of the integrated circuit 120.

FIG. 6 is a schematic view illustrating a layout of the disposition of the pad, the metal interconnections, and the metal bump illustrated in FIG. 1 on the integrated circuit 120 according to yet another embodiment of the invention. For pad structures 610, 620, 630, and 640 of the integrated circuit 120 illustrated in FIG. 6, a relevant description of FIG. 1 may be referred to. As illustrated in the embodiment of FIG. 1, the pad structures 610-640 each has a BOA structure. The pad structures 610-640 are divided into two rows. One of the rows near the edge 401 of the integrated circuit 120 includes the pad structures 610 and 620. The other row near the center 402 of the integrated circuit 120 includes the pad structures 630 and 640. In the embodiment as illustrated in FIG. 6, all of the BOA structures of the pad structures 610 and 620 on an outer row face a direction of the edge 401 of the integrated circuit 120. All of the BOA structures of the pad structures 630 and 640 on an inner row face a direction of the center 402 of the integrated circuit 120.

FIG. 7 is a schematic view illustrating a layout of the disposition of the pad, the metal interconnections, and the metal bump illustrated in FIG. 1 on the integrated circuit 120 according to yet another embodiment of the invention. For pad structures 710, 720, 730, and 740 of the integrated circuit 120 illustrated in FIG. 7, a relevant description of FIG. 1 may be referred to. As illustrated in the embodiment of FIG. 1, the pad structures 710-740 each has a BOA structure. The pad structures 710-740 are divided into two rows. One of the rows near the edge 401 of the integrated circuit 120 includes the pad structures 710 and 720. The other row near the center 402 of the integrated circuit 120 includes the pad structures 730 and 740. In the embodiment as illustrated in FIG. 7, all of the BOA structures of the pad structures 710-740 face a direction of the edge 401 of the integrated circuit 120.

As described above, whether the BOA structures of the pad structures are disposed on the edge direction of the integrated circuit 120 or disposed on the center direction of the integrated circuit 120 may be determined according to a design requirement/specification of an actual product. For example, based on a consideration of preventing the metal bump from being deformed due to an external impact during a production process, a position and a direction of where the metal bump is placed on the integrated circuit and the corresponding position of an opening of the pad may all be adjusted correspondingly. In addition, a flatness of a part of the pad may be improved by a grinding process.

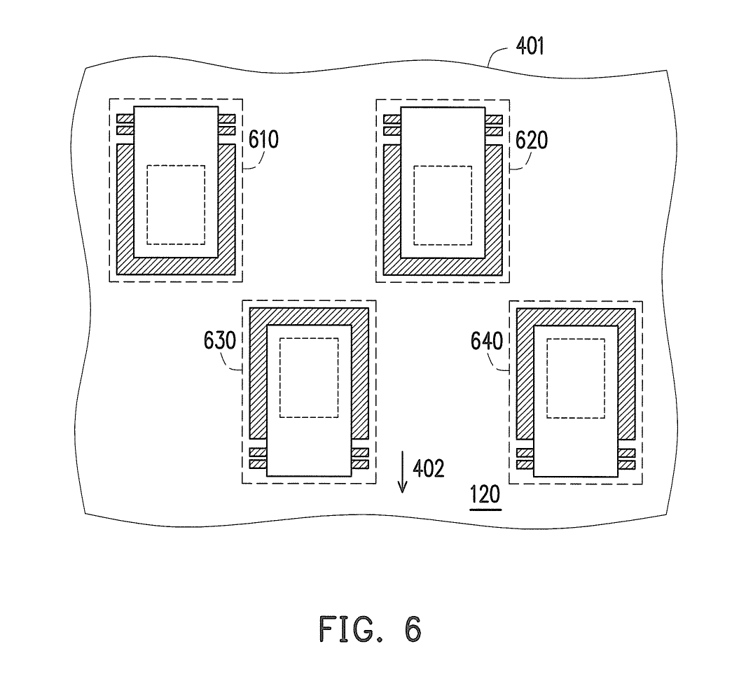

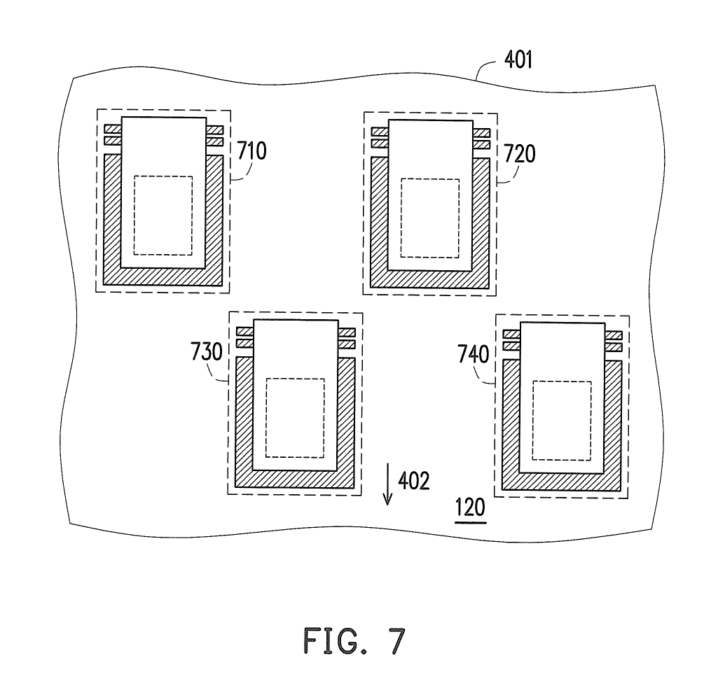

FIG. 8 is a schematic top view of a COF device 800 according to another embodiment of the invention. For the embodiment illustrated in FIG. 8, a relevant description of FIG. 1 may be referred to. FIG. 9 is a schematic cross-sectional view along the line B-B′ in FIG. 8, illustrating the COF device 800 according to an embodiment of the invention. Referring to FIGS. 8 and 9, the COF device 800 includes a flexible circuit film 110 and an integrated circuit 820. The flexible circuit film 110 includes a film 111 and at least a wire 112. The wire 112 with a conductive material is disposed on a surface of the film 111.

A substrate 830 of the integrated circuit 820 illustrated in FIG. 9 is only schematically presented. In fact, there may be various kinds of electrical elements, doped regions, metal layers, insulating layers, polysilicon layers, contact plugs, via plugs and/or other integrated circuit components inside, above, or under the substrate 830. The integrated circuit 820 further includes a metal bump 821, an adhesive layer 822, a passivation layer 823, a pad 824, and at least a metal interconnection (such as 921, 922, 923, and 924 illustrated in FIGS. 8 and 9). For the metal bump 821, the adhesive layer 822, the passivation layer 823, the pad 824, the first metal interconnections 921 and 922, and the second metal interconnections 923 and 924 illustrated in FIGS. 8 and 9, a relevant description of the metal bump 121, the adhesive layer 122, the passivation layer 123, the pad 124, and the metal interconnections 126 and 127 illustrated in FIGS. 1-3 may be referred to, respectively.

The passivation layer 823 is disposed on the substrate 830 of the integrated circuit 820. The passivation layer 823 includes a hole 825. The pad 824 is disposed under the passivation layer 823 and on the substrate 830. As illustrated in FIGS. 8 and 9, at least a part of the pad 824 is disposed under the hole 825. A metal layer 910 is disposed under the pad 824, and the metal layer 910 is electrically connected to the pad 824. The metal interconnections 921-924 and the metal layer 910 belong to a same layer. At least a part of the first metal interconnections 921 and 922 is disposed under the metal bump 821 and on a first side of the pad 824 (the metal layer 910). The second metal interconnections 923 and 924 are disposed under the passivation layer 823 and on a second side of the pad 824 (the metal layer 910). None of the metal interconnections 921-924 touches the pad 824.

The metal bump 821 includes a first part 821A, a second part 821B, and a third part 821C. At least a part of the first part 821A along the perpendicular direction Z of the COF device 800 overlaps the pad 824. The second part 821B extends to an outside of the pad 824 along a first horizontal direction Y of the COF device 800, and at least part of the second part 821B overlaps the first metal interconnections 921 and 922. The third part 821 C extends to the outside of the pad 824 along a second horizontal direction -Y of the COF device 800, and at least a part of the third part 821C overlaps the second metal interconnections 923 and 924 along the perpendicular direction Z of the COF device 800.

Even though the second metal interconnections 923 and 924 are illustrated to be disposed on a bottom side of FIG. 8, the invention is not limited thereto. In other embodiments, the second metal interconnections may be disposed on other sides of the pad 824, such as the left side or the right side of FIG. 8. Corresponding to a disposition of the second interconnections, the third part 821C of the metal bump 821 may extend to the outside of the pad 824 along another horizontal direction (such as X direction or -X direction) of the COF device 800.

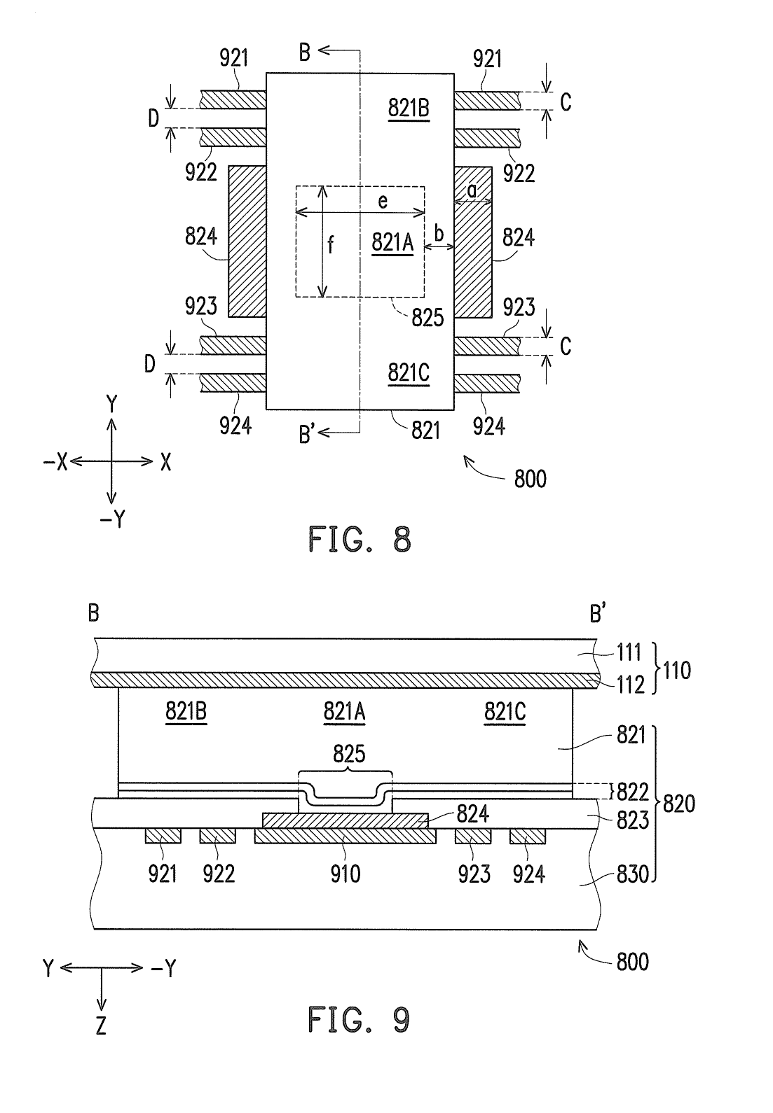

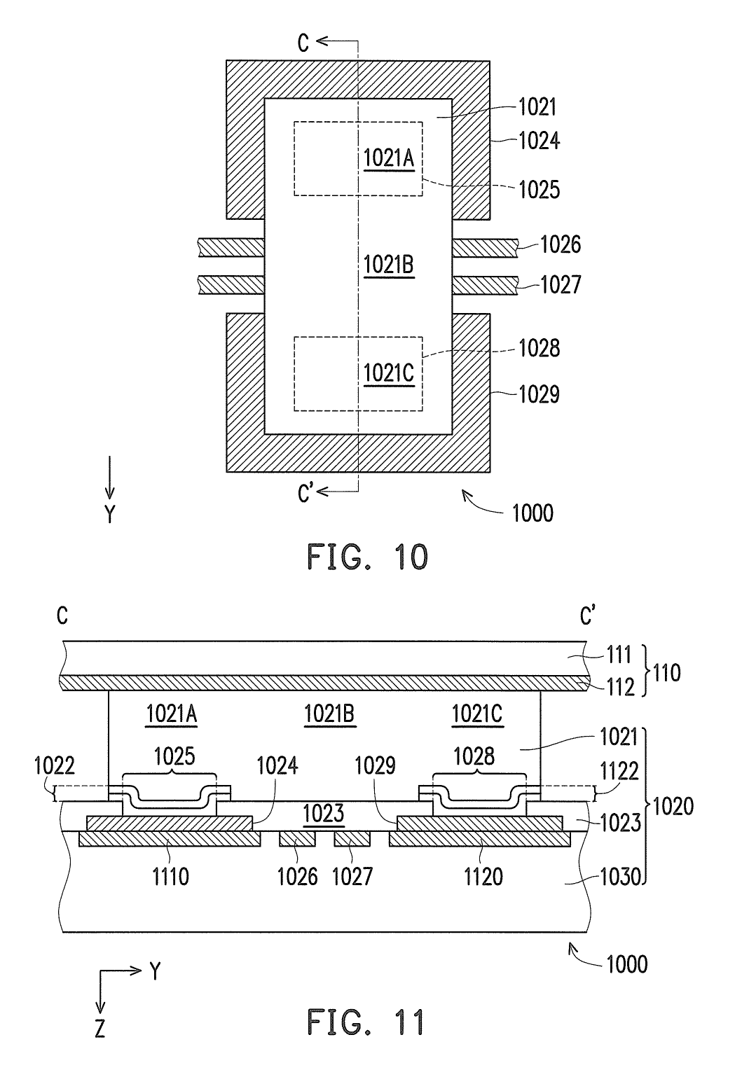

FIG. 10 is a schematic top view of a COF device 1000 according to yet another embodiment of the invention. For the embodiment illustrated in FIG. 10, a relevant description of FIG. 1 may be referred to. FIG. 11 is a schematic cross-sectional view along the line C-C′ in FIG. 10, illustrating the COF device 1000 according to an embodiment of the invention. Referring to FIGS. 10 and 11, the COF device 1000 includes a flexible circuit film 110 and an integrated circuit 1020. The flexible circuit film 110 includes a film 111 and at least a wire 112. The wire 112 with a conductive material is disposed on a surface of the film 111.

A substrate 1030 of the integrated circuit 1020 illustrated in FIG. 11 is only schematically presented. In fact, there may be various kinds of electrical elements, doped regions, metal layers, insulating layers, polysilicon layers, contact plugs, via plugs and/or other integrated circuit components inside, above, or under the substrate 1030. The integrated circuit 1020 further includes a metal bump 1021, a first adhesive layer 1022, a passivation layer 1023, a first pad 1024, a metal interconnection 1026, a metal interconnection 1027, a second adhesive layer 1122, and a second pad 1029. For the metal bump 1021, the first adhesive layer 1022, the passivation layer 1023, the first pad 1024, the metal interconnection 1026, the metal interconnection 1027, the second adhesive layer 1122, and the second pad 1029 illustrated in FIGS. 10 and 11, a relevant description of the metal bump 121, the adhesive layer 122, the passivation layer 123, the pad 124, and the metal interconnections 126 and 127 illustrated in FIGS. 1-3 may be referred to respectively.

The passivation layer 1023 is disposed on the substrate 1030 of the integrated circuit 1020. The passivation layer 1023 includes a first hole 1025 and a second hole 1028. The first pad 1024 and the second pad 1029 are disposed under the passivation layer 1023 and on the substrate 1030. As illustrated in FIGS. 10 and 11, at least a part of the first pad 1024 is disposed under the first hole 1025, and at least part of the second pad 1029 is disposed under the second hole 1028. A first metal layer 1110 is disposed under the first pad 1024, and the first metal layer 1110 is electrically connected to the first pad 1024. A second metal layer 1120 is disposed under the second pad 1029, and the second metal layer 1120 is electrically connected to the second pad 1029. The metal interconnections 1026-1027, the first metal layer 1110, and the second metal layer 1120 belong to a same layer. At least a part of the metal interconnections 1026 and 1027 is disposed under the metal bump 1021 and positioned between the first pad 1024 (the first metal layer 1110) and the second pad 1029 (the second metal layer 1120). The metal interconnections 1026 and 1027 are disposed under the passivation layer 1023. Neither of the metal interconnections 1026 and 1027 touches the pads 1024 and 1029.

The metal bump 1021 includes a first part 1021A, a second part 1021B, and a third part 1021C. At least a part of the first part 1021A along the perpendicular direction Z of the COF device 1000 overlaps the first pad 1024. The second part 1021B extends to an outside of the first pad 1024 along a horizontal direction Y of the COF device 1000, and at least part of the second part 1021B overlaps the metal interconnections 1026 and 1027. The third part 1021C extends to the outside of the first pad 1024 along the horizontal direction Y of the COF device 1000, and at least a part of the third part 1021C overlaps the second pad 1029 along the perpendicular direction Z of the COF device 1000.

The first adhesive layer 1022 and the second adhesive layer 1122 may be titanium tungsten layers or other conductive layers. The first adhesive layer 1022 and the second adhesive layer 1122 are disposed on the passivation layer 1023. A part of the first adhesive layer 1022 is disposed in the first hole 1025. A part of the second adhesive layer 1122 is disposed in the second hole 1028. At least a part of the metal bump 1021 is disposed on the first adhesive layer 1022, and the metal bump 1021 is electrically connected to the first pad 1024 via the first adhesive layer 1022. At least another part of the metal bump 1021 is disposed on the second adhesive layer 1122, and the metal bump 1021 is electrically connected to the second pad 1029 via the second adhesive layer 1122.

As described above, in the embodiments of the invention, the first part of the metal bump overlaps the pad along the perpendicular direction of the COF device, and the second part of the metal bump overlaps the metal interconnection (such as a supply wire, a ground wire, a data wire, or other wires) outside the pad. Moreover, the metal bump may overlap the metal interconnections and form a Bump on Active (BOA) structure. Therefore, the COF device in the embodiments of the invention is capable of effectively reducing the area of the pad to facilitate the routing design of the metal interconnections.

Although the invention has been described with reference to the above embodiments, they are not intended to limit the invention. It is apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A chip-on-film (COF) device, comprising:
a flexible circuit film having at least a wire;
a passivation layer having a first hole;
a first adhesive layer, at least a part of the first adhesive layer being disposed in the first hole;
a first pad disposed under the passivation layer, and at least a part of the first pad being disposed under the first hole;
a second pad disposed under the passivation layer and on a first side of the first pad,
a first metal interconnection, at least a part of the first metal interconnection being disposed under the passivation layer and disposed at the first side of the first pad and disposed between the first pad and the second pad, wherein the first metal interconnection does not touch the first pad and the second pad; and
a metal bump, at least a part of the metal bump being disposed on the first adhesive layer, and the metal bump being electrically connected to the first pad via the first adhesive layer and welded on the at least one wire,
wherein the metal bump comprises a first part, a second part and a third part, wherein at least a part of the first part overlaps the first pad along a perpendicular direction of the COF device, the second part extends to an outside of the first pad along a first horizontal direction of the COF device and partially overlaps the first metal interconnection, and at least part of the third part overlaps the second pad along the perpendicular direction of the COF device.

2. The COF device according to claim 1, wherein an area ratio of the first hole and the metal bump is 20% to 40% on the perpendicular direction of the COF device.

3. The COF device according to claim 1, wherein a hardness of the metal bump is 25-100 Hv.

4. The COF device according to claim 3, wherein the hardness of the metal bump is 40-70 Hv.

5. The COF device according to claim 4, wherein the hardness of the metal bump is 40-50 Hv.

6. The COF device according to claim 1, wherein a surface roughness of the metal bump is 0.05-2 μm.

7. The COF device according to claim 6, wherein the surface roughness of the metal bump is 0.8-1.2 μm.

8. The COF device according to claim 1, wherein the first pad is an aluminum pad or a gold pad.

9. The COF device according to claim 1, wherein the metal bump is a gold bump.

10. The COF device according to claim 1, wherein the first adhesive layer is a titanium tungsten layer.

11. The COF device according to claim 1, further comprising at least a metal layer disposed under the first pad and next to the first metal interconnection.

12. The COF device according to claim 1, wherein a shorter side of the first hole is greater than 12 μm, a longer side of the first hole is greater than 35 μm, a distance from an edge of the first hole to an edge of the metal bump is greater than 3 μm, a distance from an edge of the first part of the metal bump to an edge of the first pad is greater than 3 μm, a width of the first metal interconnection is 0.1 μm to 40 μm, and a distance from an edge of the first metal interconnection to the edge of the first pad is greater than 0.1 μm on the perpendicular direction of COF device.

13. The COF device according to claim 1, wherein
the insulating layer further comprises a second hole,
the COF device further comprises a second adhesive layer, at least a part of the second adhesive layer being disposed in the second hole, and
at least another part of the metal bump is disposed on the second adhesive layer, and the metal bump is electrically connected to the second pad via the second adhesive layer.

14. The COF device according to claim 13, wherein the second adhesive layer is a titanium tungsten layer.
